(19) United States
(12) Patent Application Publication
(10) Pub. No.: US 2017/0276721 A1
(43) Pub. Date: Sep. 28, 2017

(54) PROCESS AND ASSEMBLY FOR TESTING ELECTRICAL AND OPTICAL PARAMETERS OF A PLURALITY OF LIGHT-EMITTING DEVICES

(71) Applicants: Rasco GMBH, Kolbermoor (DE); Ismeca Semiconductor Holding SA, La Chaux-de-Fonds (CH)

(72) Inventors: Massimo SCARPELLA, Les Brenets (CH); Sasa NESTOROVIC, Escondido, CA (US)

(73) Assignees: RASCO GmbH, Kolbermoor (DE); Ismeca Semiconductor Holding SA, La Chaux-De-Fonds (CH)

(21) Appl. No.: 15/507,141

(22) PCT Filed: Sep. 30, 2015
(86) PCT No.: PCT/EP2015/072559

§ 371 Date: Feb. 27, 2017

(30) Foreign Application Priority Data
Nov. 5, 2014 (EP) 14191888.8

(51) Int. Cl. G01R 31/26; G01R 31/265

(52) U.S. Cl. CPC G01R 31/2601; G01R 31/2653; G06T 2207/30148

(57) ABSTRACT

According to the present invention there is provided a method for testing electrical and optical parameters of a group of light-emitting devices, the method comprising the steps of, bringing the group of devices to a test position wherein light emitted by the devices in the group can be received into an integrating sphere; performing, electrical testing of the devices in the group in parallel, so that electrical parameters of each of the devices in the group can be determined; performing, in a sequential device-by-device manner, optical testing of the devices in the group, so that optical parameters of each of the devices in the group can be determined. There is further provided a corresponding assembly.

### FIELD OF THE INVENTION

The present invention relates to a process for testing electrical and optical parameters of a plurality of light-emitting devices, wherein the electrical testing is performed on the all of the plurality of light emitting devices in parallel, and optical testing of the devices is performed in a sequential device-by-device manner.

### BACKGROUND

Light-emitting semiconductor devices, such as LEDs or laser diodes or fluorescent bulbs etc., for high-end applications, have to be tested after manufacturing, both with regard to important optical and electrical parameters. Test procedures and apparatus' for implementing such tests at mass production level are well-known.

For testing high-end devices, the optical testing is carried out in an integrating sphere (Ulbricht sphere), wherein the light emitted by the device is integrated. Although the light-emitting devices are, as in the mass production testing of other semiconductor devices, fed to the test device on a matrix-type test array, the testing is made piece-by-piece. In each device testing step, the respective device is brought to a dedicated test position, i.e. to a small opening in the wall of the integrating sphere, and aligned to emit light into the sphere. When testing a plurality of devices which are arranged on a test array, the test array is sequentially shifted in a xy manner, so that all of the devices are brought to the tiny opening which defines the test position. In well-established test procedures, the electrical testing is carried out likewise piece-by-piece, immediately, in advance of or after the optical testing.

In such established test procedures and corresponding arrangements, the time periods required for the electrical and optical testing and the even more significant handling times for bringing each device to the test position sum up to at least some minutes, for testing all devices of a test array. Moreover, in such procedures it is impossible to fully shield the device under test from ambient light, so that the measured optical values include an offset.

It is an objective of the present invention, to provide for an improved process and apparatus for commonly testing electrical and optical parameters of a plurality of light-emitting devices which are arranged in a test array. In particular, the process and apparatus shall provide improvements in terms of overall test time per device and/or in terms of the accuracy of the optical measurements.

### SUMMARY OF INVENTION

The present invention achieves the aforementioned objective in its process aspect, with a process comprising the features of claim 1. In its apparatus aspect, the present invention achieves the aforementioned objective by a test arrangement comprising the features of claim 8. Optional features which may be present embodiments of the invention are the subject of the dependent claims.

It is an aspect of the invention, to bring a group of light-emitting devices to a common test position for carrying out the sequential optical tests, without changing the position of the group between the optical test steps. In other words, a test position is no longer defined as a “point” which has the dimensions of a single device but rather as an area which has the dimensions of at least a group of devices. Since in such extended (plane) test area the exact position and main axis of light emission of the several devices with respect to the center of the integrating sphere are slightly different, these differences have to be neglected or can be taken into account by a predetermined post-processing of the measured optical values.

Whereas according to the above aspect of the invention the basic piece-by-piece approach of the prior art in optical testing is maintained, according to a further aspect of the invention the electrical testing is no longer carried out on a piece-by-piece basis but rather in parallel for a group of devices, using a multi-channel or multiplexing scheme, respectively.

According to a third aspect of the invention, the contacting of the devices for carrying out the electrical and optical tests is likewise made simultaneously for a group of devices.

Note that in all referenced aspects of the invention the term “group” does not necessarily, and not even in terms of the practical implementation, mean the same group of devices: Whereas the group of devices which are brought to a common test position for the optical testing can well be the total number of devices on the test array, the group to be simultaneously contacted can rather be a single row of the test array (but also more than one single row). The group of devices which are simultaneously electrically tested can comprise any number of devices e.g. four or eight devices, depending on cost aspects for implementing the required number of separate test channels, including the required routing of the measured signals to a measuring and evaluating unit.

It should also be mentioned that the term “integrating sphere” shall not be limited to exactly spherical light integrating bodies. Rather, this term shall also cover hemispherical or dome-type integrating surfaces and even hollow bodies which do not even have a spherical or ellipsoidal portion, e.g. cylindrical or conical or other integrating surfaces. Likewise, the term “integrating sphere unit” shall cover measuring units which comprise such integrating surfaces.

The term “test array” shall be understood as covering both arrangements of singulated light-emitting devices (arranged on an array for the purpose of testing only) and solid panels of light-emitting devices.

In an embodiment of the invention, the process comprises post-processing the determined values of the optical parameters according to the individual position of the respective device relative to the center of the integrating sphere in the optical test step. Such post-processing is based on a predetermined algorithm, in which the distance of a respective light-emitting device on the plane test array to the center of the test array is taken into account. However, as mentioned above, depending on the required accuracy of the optical measurements in other embodiments of the invention such post-processing may be dispensed with.

In a further embodiment, the test array has rows and columns, each of which comprises plural groups of devices to be electrically tested in parallel, and all devices of at least one row are simultaneously contacted at least for the electrical test steps of all groups of the row(s) by means of a row contactor unit. In another embodiment only some of the devices of at least one row are simultaneously contacted at least for the electrical test steps of by means of a row contactor unit.

Whereas presently such row contactor unit appears as a preferable type of contactor unit for the testing, the invention can likewise be implemented with other types of contactor units, including multi-row contactor units or group contactor units which are not configured in accordance with rows or columns of the test array.

In this regard, it should be emphasized that the test array is not necessarily a matrix-type array but can likewise be a multi-ring circular or spiral arrangement or any other type of predetermined regular arrangement of light-emitting devices on a test carrier.

In a further embodiment of the invention, the position of the test array (or a sub-array) in the opening of the integrating sphere is optically tightly sealed against ambient light. This advantageous optical sealing, which significantly improves the precision of the optical tests, is made possible or at least facilitated by keeping a group of devices, which are commonly optically sealed, or the whole test array in an invariant position relative to the center of the integrating sphere during the piece-by-piece optical tests.

As already mentioned above, in a further embodiment of the invention the devices are brought to the test position by initially moving the test array into an opening of the integrating sphere, and this initial test position of the test array is maintained during the electrical and optical testing of all devices. On the other hand, the group of devices which are commonly brought to a test position and during the piece-by-piece testing kept in that position, can be smaller than complete test array, i.e. a predetermined sub-array which is configured to be optically tightly sealed.

In a preferred handling procedure of the devices to the test position, at the same time preparing the simultaneous contacting step, the test array is brought to the opening of the integrating sphere by means of a plunger head on which the test array is being held. In a first step the plunger head is moved to the integrating sphere, to a position below the opening, and in a second step, which can be combined with the first step, the plunger head is elevated radially to the integrating sphere. At the end of this feeding procedure, the test array enters the opening of the integrating sphere, i.e. the predetermined test position. In a third step the test array is released from the plunger head and docked to the integrating sphere, and in a fourth step the plunger head is lowered from the integrating sphere.

Thereafter, in a further embodiment, the simultaneous contacting of the devices is made by means of a contactor unit, preferably a row contactor unit, embedded in the plunger head. The contact is made by elevating the plunger head to the test array in an appropriate position of the contactor unit relative to the test array, and sucking or pressing the plunger head surface, with the contacting elements provided therein, against the test array.

According to a device aspect of the invention, the integrating sphere unit has an opening adapted to the geometrical configuration of the test array or a sub-array and docking means to hold the test array docked in an invariant test position during the optical test steps for all devices on the test array or sub-array, respectively. According to a further device aspect, the integrating sphere is provided with optical sealing means for tightly sealing the devices on the test array or sub-array against ambient light.

It is a further aspect of the proposed test arrangement, that the test handler is configured to feed the test array to the test position within the integrating sphere and to release the test array or sub-array after the feeding step. At that stage of the test handling, the docking means of the integrating sphere unit take over, to hold the test array or sub-array in the test position.

As mentioned above under process aspects, in a further embodiment of the test arrangement the plunger head comprises a row contactor unit having contacting means for simultaneously contacting all devices in at least one row of the test array or for simultaneously contacting some of the devices in at least one row of the test array. Once again, please note that different embodiments are possible, wherein the contactor unit is not configured for row-wise or column-wise contacting of the light-emitting devices but rather for simultaneously contacting a differently defined group of devices.

In a further embodiment, the integrating sphere unit and/or the plunger head comprise controllable vacuum suction means for holding or releasing, respectively, the test array. However, the implementation of the docking means associated to the integrating sphere is not limited to such suction means. Rather, the docking means can comprise a magnetic lock or a simple mechanical lock, e.g. by means of pivotable, motor-driven locking brackets or similar.

In a more specific implementation, the plunger head comprises first controllable suction means for holding the test array on the plunger head during the feeding step to the integrating sphere and for releasing it after the feeding step, and second controllable suction means for sucking the contactor unit against the test array, to provide an electrical connection between the contactor unit and the device contacts during a respective test step. By providing independent suction means for the referenced purposes, the holding force in the respective steps can easily be adjusted.

In a further embodiment, the contactor unit in the plunger head comprises a plurality of contact pins, the configuration of which is adapted to the number electrical test channels and to the configuration of the device contacts. Furthermore, the contactor unit preferably comprises a multi-layered printed circuit board comprising leads which are arranged in accordance with the configuration of the contact pins. A plurality of output contacts is connected to the leads of the printed circuit board, for outputting electrical signals which have been routed from the devices through the plunger head, to the test control and measuring unit. By means of such contact pin/PCB arrangement, specifically in implementations with a quite large number of electrical test channels a simple and compact signal transmission unit is being provided.

Further simplification and even more compact design can be achieved in a more specific embodiment, wherein the integrating sphere unit likewise comprises a printed circuit board provided with input contacts adapted to the output contacts of the plunger head, for further routing the signals from the devices to the test control and measuring unit.

In a further embodiment, as mentioned further above under process aspects, the test control and measuring unit comprises optical parameter post-processing means for post-processing measured values of the optical parameters in accordance with the individual position of the respective devices with respect to the center of the integrating sphere, in the optical test step.

Further embodiments and aspects of the invention are explained below with reference to the figures.

According to the present invention there is provided a method for testing electrical and optical parameters of a group of light-emitting devices, the method comprising the steps of, bringing the group of devices to a test position wherein light emitted by the devices in the group can be received into an integrating sphere; performing, electrical testing of the devices in the group in parallel, so that electrical parameters of each of the devices in the group can be determined; performing, in a sequential device-by-device manner, optical testing of the devices in the group, so that optical parameters of each of the devices in the group can be determined.

The method may comprise the step of, bringing a plurality of groups of devices to a test position wherein light emitted by the devices in the plurality of groups can be received into an integrating sphere; and for each group in the plurality of groups of devices, performing, electrical testing of the devices in the group in parallel, so that electrical parameters of each of the devices in the group can be determined, and performing, in a sequential device-by-device manner, optical testing of the devices in the group, so that optical parameters of each of the devices in the group can be determined, and where the optical testing and/or electrical testing of the plurality of groups of devices is performed without moving the plurality of groups of devices from the initial test position to which the plurality of groups of devices were initially brought, so that the plurality of groups of devices are maintained in said test position as optical testing and electrical testing is performed on all devices in the plurality of groups of device.

The method may comprise the steps of, mechanically contacting a plurality of electrical contact pins with electrical contacts of all devices in the group, so that the plurality of electrical contact pins simultaneously mechanically contact electrical contacts of all devices in the group; wherein each of the plurality of electrical contact pins can be used to supply electrical signals which implement said optical testing and/or can be used to supply electrical signals which implement said electrical testing.

The step of performing said electrical testing may comprise, passing electrical signals which implement said electrical testing through each of the plurality of electrical contact pins simultaneously so that electrical testing of all the devices in the group is performed simultaneously.

The step of performing said optical testing may comprise, passing electrical signals which implement said optical testing through each of the test contacts sequentially so that optical testing of all the devices in the group is performed in a sequential device-by-device manner.

The method may comprise the step of using a multiplexer to pass said electrical signals which implement said optical testing to each of the test contacts sequentially.

In another alternative embodiment the method may comprise the steps of, (i) mechanically contacting electrical contact pins with electrical contacts of a single device only; wherein said electrical contact pins can be used supply electrical signals which implement said optical testing, (ii) passing electrical signals which implement said optical testing through the electrical contact pins so that optical testing of said single device is performed; (iii) repeating the steps (i) and (ii) for each of the devices in the group so that optical testing of the devices in the group is performed in a sequential device-by-device manner.

The step of performing electrical testing of the devices in the group in parallel may be performed prior to the step of performing optical testing of the devices in the group in a sequential device-by-device manner.

The method may further comprise the steps of, determining, based on the optical testing, optical parameters of each of the devices in the group; post-processing said optical parameters of each of the devices in the group, according to the position of the respective device relative to the center of the integrating sphere when the group is in said test position.

In the present invention a group of device may comprise a number of devices. Preferably a group of devices comprises a more than two devices. The group of devices may be positioned on a tray. The group of light-emitting devices may be provided as a test array. The group of light-emitting devices may be a plurality of singulated light-emitting devices arranged in an array for the purpose of testing only and/or the group of light emitting devices may be provided as a plurality of non-singulated light-emitting devices i.e. single light emitting element which comprises a plurality of light emitting devices or a solid panel of light-emitting devices

The method may comprise using a carrier to bring the group of devices to a test position, wherein the carrier comprises a nest which comprises a flat surface on which a group of devices can be supported, and wherein the nest is configured such that no part of the nest extends above the plane of the surface, and wherein each of the group of devices are supported on the flat surface so that each of the group of devices is above the nest.

Thus in this embodiment the flat surface defines the top surface of the nest; specifically the flat surface defines the uppermost surface of the nest. This ensures that no part of the nest will obstruct light emitted by the devices. Also the flat surface allows any sized device to be supported on the nest, so the carrier is not limited to carry devices of specific dimensions.

The carrier may further comprise a vacuum opening defined in a surface of the carrier, and which is fluidly connected to a vacuum generator, so that a vacuum can be provided at the surface which holds the group of devices on the surface of the carrier. In one embodiment the vacuum provided at the surface holds a tile on which the devices are supported.

The method may further comprise the step of providing a vacuum force at a surface of the carrier to prevent the group devices from becoming displaced from the surface of the carrier.

Preferably the nest comprises a means by which a vacuum force may be applied to the group of devices which it supports, to hold the group of devices on the nest.

Preferably the means by which a vacuum force may be applied to the group of devices comprises a conduit which is configured to be in fluid communication with the flat surface of the nest and can be configured to be in fluid communication with a vacuum generating means. Preferably the conduit is integral to the nest. Preferably a vacuum generating means is arranged in fluid communication with the conduit.

Preferably there is further provided a detection means operable to detect the orientation of a device which supported on the carrier (e.g. nest).

The nest may be provided on an index table. For example an index table may comprise a plurality of nests, each of which have a flat surface on which a group of devices can be supported.

The group of devices may be provided on a strip. The group of devices may be provided on a tray.

A method may comprise using a carrier to bring the group of devices to a test position, wherein the carrier comprises a plunger head on which the group of devices can be supported, and wherein said step of bringing the group of devices to a test position may comprise, moving the carrier such that the plunger head, on which a tile containing the group of devices is supported, to a position below an inlet of a light integrating sphere, moving the plunger head so that the tile is docked into a docking means which holds the tile in a position such that the group of devices are maintained in said test position.

The method may further comprise the steps of, applying a vacuum to the tile to hold the tile on the plunger head as the carrier and plunger head are moved; and removing the vacuum applied to the tile after the tile has been docked into the docking means.

The plurality of electrical contact pins may be provided in a plunger head of a carrier, and wherein the step of mechanically contacting a plurality of electrical contact pins with electrical contacts of all devices in the group, so that the plurality of electrical contact pins simultaneously mechanically contact electrical contacts of all devices in the group, may comprise, applying a vacuum force to a tile on which the group of devices are supported, to suck the tile towards the plunger head and/or suck the plunger head towards the tray; and extending said plurality of electrical contact pins to mechanically contact the electrical contacts of all devices in the group.

In a preferred embodiment the steps of applying a vacuum force to the tile and extending said plurality of electrical contact pins are performed simultaneously.

According to a further aspect of the present invention there is provided an assembly suitable for performing the method according to any one of the above-mentioned methods, the assembly comprising, a light integrating sphere; a carrier for bringing the group of devices to a test position wherein light emitted by the devices in the group can be received into an integrating sphere; a test control and parameter measuring unit for performing, electrical testing of the devices in the group in parallel, so that electrical parameters of each of the devices in the group can be determined, and for performing, in a sequential device-by-device manner, optical testing of the devices in the group, so that optical parameters of each of the devices in the group can be determined.

The assembly may comprise, a plurality of electrical contact pins which can be selectively moved to mechanically contact the electrical contacts of all devices in the group, so that the electrical contact pins simultaneously mechanically contact respective electrical contacts of all devices in the group; wherein each of the plurality of electrical contact pins can be used to supply electrical signals which implement said optical testing and/or can be used to supply electrical signals which implement said electrical testing.

The test control and parameter measuring unit may be configured to initiate passing electrical signals which implement said optical testing through each of the electrical contact pins sequentially so that optical testing of all the devices in the group is performed in a sequential device-by-device manner.

The test control and parameter measuring unit may be configured to initiate passing electrical signals which implement said electrical testing, through each of the plurality of electrical contact pins simultaneously so that electrical testing of all the devices in the group is performed simultaneously.

Preferably the test control and parameter measuring unit may be configured to perform said electrical testing prior to performing optical testing. The test control and parameter measuring unit may be configured to initiate the passing of electrical signals which implement said electrical testing through each of the electrical contact pins simultaneously, prior to initiating passing electrical signals which implement said optical testing through each of the electrical contact pins sequentially.

According to a further aspect of the present invention there is provided an assembly may further comprise, a plurality of electrical contact pins which can be selectively moved to mechanically contact the electrical contacts of all devices in the group, so that the electrical contact pins simultaneously mechanically contact respective electrical contacts of all devices in the group; wherein each of the plurality of electrical contact pins can be used to supply electrical signals which implement said optical testing and/or can be used to supply electrical signals which implement said electrical testing; and wherein the test control and parameter measuring unit is configured to initiate passing electrical signals which implement said optical testing through each of the electrical contact pins sequentially so that optical testing of all the devices in the group is performed in a sequential device-by-device manner, and wherein the test control and parameter measuring unit is configured to initiate passing electrical signals which implement said electrical testing comprises, through each of the plurality of electrical contact pins simultaneously so that electrical testing of all the devices in the group is performed simultaneously.

The assembly may further comprise a means for maintaining the group of devices in said test position as the optical testing and electrical testing of the devices in the group is performed; and wherein the test control and parameter measuring unit 3 is configured to determine based on the optical testing, optical parameters of each of the devices in the group, and to post-process said optical parameters of each of the devices in the group, according to the position of the respective device relative to the center of the integrating sphere when the group is in said test position.

The assembly may further comprise, a plurality of electrical contact pins which can be selectively moved to mechanically contact the electrical contacts of all devices in the group, so that the electrical contact pins simultaneously mechanically contact respective electrical contacts of all devices in the group; wherein each of the plurality of electrical contact pins can be used to supply electrical signals which implement said optical testing and/or can be used to supply electrical signals which implement said electrical testing.

The assembly may further comprise a multiplexer which has an input connected to the test control and parameter measuring unit and a plurality of selectively addressable outputs which are connected to a respective electrical contact pin.

The test control and parameter measuring unit may be configured to initiate passing electrical signals which implement said optical testing through each of the electrical contact pins sequentially so that optical testing of all the devices in the group is performed in a sequential device-by-device manner.

The test control and parameter measuring unit may be configured to initiate passing electrical signals which implement said electrical testing comprises, through each of the plurality of electrical contact pins simultaneously so that electrical testing of all the devices in the group is performed simultaneously.

The carrier may comprise a nest which comprises a flat surface on which a group of devices can be supported, and wherein the nest is configured such that no part of the nest extends above the plane of the surface.

Thus in this embodiment the flat surface defines the top surface of the nest; specifically the flat surface defines the uppermost surface of the nest. This ensures that no part of the nest will obstruct light emitted by the devices. Also the flat surface allows any sized device to be supported on the nest, so the carrier is not limited to carry devices of specific dimensions.

The carrier may further comprise a vacuum opening defined in a surface of the carrier, and which is fluidly connected to a vacuum generator, so that a vacuum can be provided at the surface which holds the group of devices on the surface of the carrier. In one embodiment the vacuum provided at the surface holds a tile on which the devices are supported.

The carrier may comprise a plunger head which can be selectively extended from the carrier, and wherein the plunger head further comprises a surface on which a group of devices (e.g. a tile containing a group of devices) can be supported.

The surface of the carrier may further comprise strips which are arranged to protrude from grooves defined in the surface of the plunger head. Preferably the strips comprise rubber.

The carrier further comprises a vacuum opening which is defined on the surface of the plunger head, which is fluidly connected to a vacuum generator.

The carrier further comprises a plurality of electrical contact pins provided in the plunger head, and which can be selectively extended to protrude above the surface of the plunger head.

The carrier further comprises a plurality of contact sockets provided in the surface of the plunger head, through which the electrical contact pins can be selectively moved. The assembly may further comprise a docking means which can hold a tile on which the group of devices are supported, so that the group of devices are maintained the test position. Preferably the docking means is configured to apply a vacuum to the tile to hold the tray.

### BRIEF DESCRIPTION OF DRAWINGS

An embodiment of the invention will now be described by way of example only, with reference to the accompanying drawings in which,

FIG. 1 shows a schematic view (partly as a block diagram) of an assembly according to an embodiment of the invention;

FIG. 2 shows a view of the lower portion of the integrating sphere, together with a plunger head in a position adjacent to the integrating sphere;

FIG. 3 is a perspective view of a plunger head, together with the test array which is shown elevated from the plunger head;

FIG. 4 shows, in a synoptical illustration providing a partial view of the lower portion of the integrating sphere and plunger head shown in FIG. 2, and includes an illustration of the flow of electrical testing signals from the devices on the test array;

FIG. 5a shows a exemplary configuration for a carrier which can be used in an assembly according to the present invention; FIG. 5b shows a magnified view of a nest of the carrier shown FIG. 5a;

FIG. 6 illustrated loading a tile of devices onto a surface of a plunger head of a test handler;

FIG. 7 illustrated the test handler which has been moved so that it is adjacent the inlet window of a light integrating sphere;

FIG. 8 illustrates the tile of light emitting devices in the test position;

FIG. 9 illustrates the test handler after it has been moved so that the contact sockets in the contact unit are aligned with electrical contacts of the light emitting devices in a first row of the test array;

FIGS. 10a & 10b illustrate a test handler after having been moved so that the strips on the surface of the plunger head abut an undersurface of the tray;

FIG. 11a illustrates the tile when a vacuum is applied to its undersurface and electrical contact pins of the contact unit have been moved to protrude from the plurality of contact socket to simultaneously mechanically contact all electrical contacts of the light emitting devices in the group;

FIG. 11b is a perspective view of a tile on which devices are supported; and shows part of an undersurface of the tile where the electrical contacts of light emitting devices are exposed;

FIG. 12 illustrates part of the assembly according to a further embodiment of the present invention, in which the nest on a rotary table is located adjacent to a window of the integrating sphere, a part-cut-away portion of the integrating sphere is provided so as provide an illustration of inside of the sphere;

FIG. 13 provides a magnified view of the nest and window inlet shown in FIG. 12.

### DETAILED DESCRIPTION

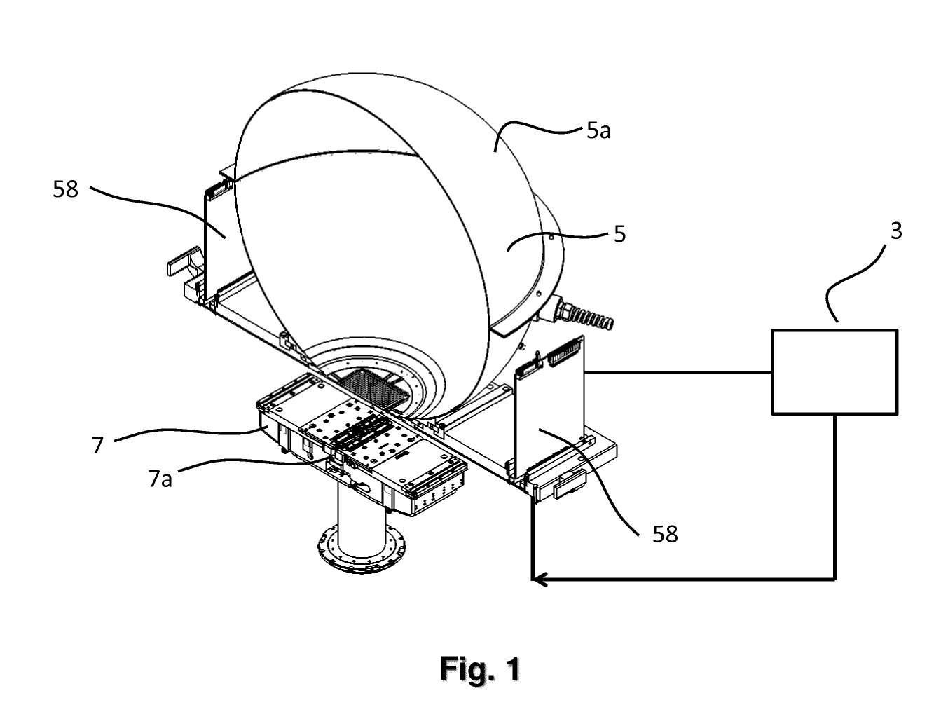

FIG. 1 shows a schematic view (partly as a block diagram) of an assembly 1 (which can be used to test electrical devices; such as light emitting devices for example) according to an embodiment of the invention. The test arrangement 1 comprises a test control and parameter measuring unit 3, an integrating sphere unit 5 and a carrier 7 in the form of a test handler 7 comprising a plunger head 7a. The test control and parameter measuring unit 3 controls a predetermined sequence of electrical and optical test steps for light-emitting devices and provides for measuring the respective electrical and optical parameters. An integrating sphere 5a (shown in cross-section in FIG. 1) of the integrating sphere unit 5 accommodates devices in a test position (see further below) and provides an integrating function with respect to the light emission of the devices. The test handler 7 with the plunger head 7a handles the devices is configured to bring devices to the test position and to electrically contact devices to that electrical signals for electrical testing and optical testing can be sent to the devices under test.

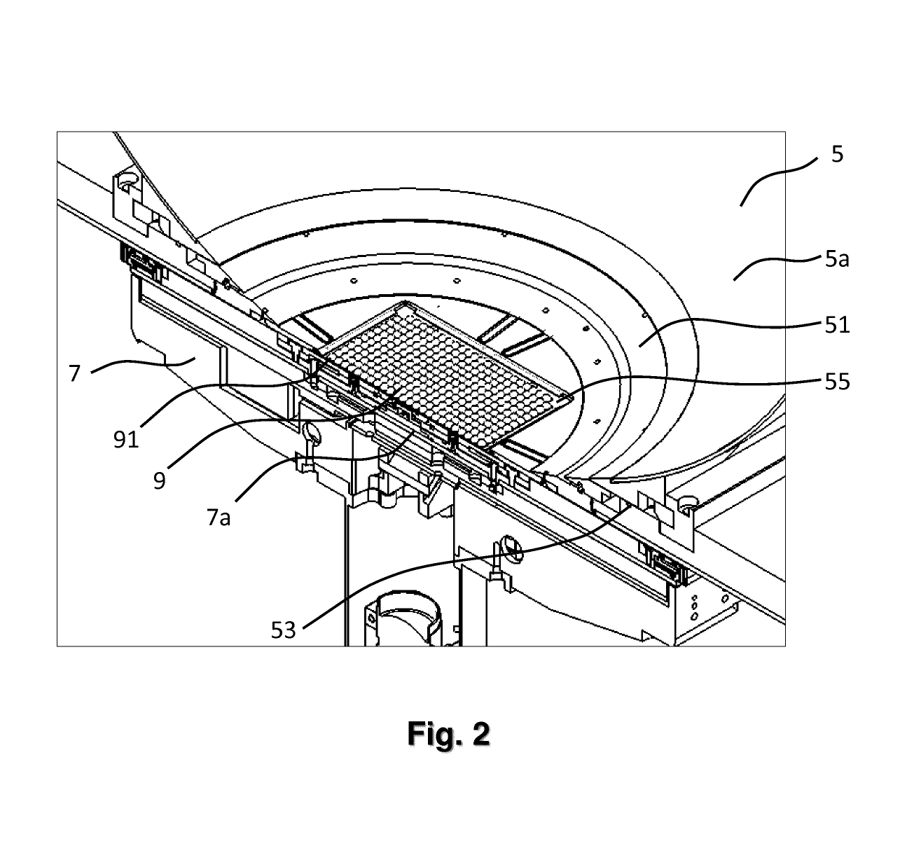

FIG. 2 shows in a detailed cross sectional view the lower portion of the integrating sphere 5a. The integrating sphere has an inlet window 51; a sealing ring 53 is provided along the perimeter of the inlet window 51 for shielding the inlet window 51 and the interior of the integrating sphere from ambient light. FIG. 2 illustrates the test handler 7 in a position directly below the inlet window 51 with the plunger head 7a substantially aligned with the center of the inlet window 51 of the integrating sphere 5a.

A test array 9 comprising a plurality of light-emitting devices 91 to be tested is located at the inlet window 51 of the integrating sphere 5a such that when the light-emitting devices 91 are operated they emit light into the integrating sphere 5a. The test array 9 shows a plurality of light emitting devices arranged in a matrix of rows and columns; however it will be understood that the test array may comprise any number of light-emitting devices 91 in any arrangement; for example in an alternative embodiment the test array 9 may comprise a single row of light-emitting devices 91 (e.g. five light-emitting devices arranged in a single row). In this example the matrix of light-emitting devices 91 is shown to be supported on a tile 55; however it will be understood that the light-emitting devices 91 could be supported on any other suitable structure such as a strip such as a flexible strip or tape.

The plunger head 7a is shown in its position immediately below the inlet window 53 and bears tile 55 holding the test array 9 on its surface. It should be understood that, once the test array 9 has been moved by the plunger head 7a into the test position, the tile 55 on which the test array 9 is supported will be released from the plunger head 7a. When the test array 9 has been moved by the plunger head 7a into the test position, a docking means in the integrating sphere unit 5 will hold the tile 55 so that the test array 9 is maintained in the test position. In this example the test position is a position in which the light-emitting devices 91 can emit light into the integrating sphere 5a. Also the tile 55 is configured to seal the integrating sphere from ambient light when it has been moved by the plunger head 7a to cooperate with the docking means in the integrating sphere unit 5. The docking means in this example comprises a vacuum unit which applies a vacuum to the tile 55 so as to hold the tile 55 so that the test array 9 is maintained in the test position.

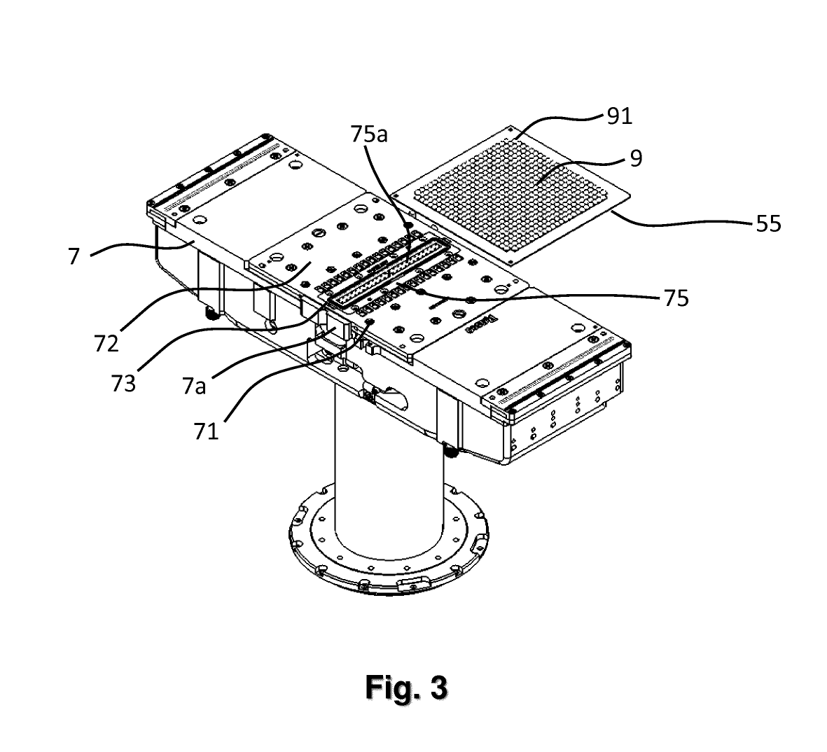

FIG. 3 is a perspective view of the test handler 7, together with the test array 9 supported on the tile 55; the test array 9 is illustrates elevated from the plunger head 7a to allow the surface 72 of the plunger head 7a to be seen. It should be noted that the plunger head 7a can extend linearly from the test handler 7 to deliver the test array 9 to a test position in the light integrating sphere 5a. A plurality of vacuum openings 71 are defined in the surface 72 of the plunger head 7a (it will be understood that any number of vacuum openings 71 may be provided, for example a single vacuum opening 71 may be provided; preferably between 10-50 vacuum openings 71 are provided); the vacuum openings 71 are each in fluid communication with a vacuum generating means (not shown) so that a vacuum can be applied to the tile 55 supported on, or abuts, the surface 72. Applying a vacuum to the tile 55 supported on the surface will serve to hold the tile 55 on the surface 72; applying a vacuum to a tile 55 which abuts the surface 72 will facilitate establishing electrical contact between contacts on the test handler 7 and the light emitting devices 91 in the test array 9 as will be described in more detail later.

A contactor unit 75 is further provided in the plunger head 7a. The contact unit comprises a plurality of electrical contact pins (not shown); the electrical contact pins can be selectively protruded through contact sockets 75a which are provided on the surface 72 of the plunger head 7a, so that the electrical contact pins extend from the surface 72 of the plunger head 7a. The electrical contact pins are protruded thought the contact sockets 75a to electrically contact the light-emitting devices 91, when the tile 55 is held by the docking means in the integrating sphere unit 5; electrical signals to implement electrical and optical testing is sent via the electrical contact pins to the light-emitting devices 91. In the embodiment shown, a plurality of contact sockets 75a, and correspondingly a plurality of electrical contact pins are provide; this enables a plurality of light-emitting devices 91 of a single row of the test array, to be simultaneously contacted.

Seal(s) 73 are provided on the surface 72. In this example the seals are composed of rubber. In this example the seal(s) 73 are provided on the surface and the seals are arranged to extend along a respective rectantular groove (having rounded edges). Each seal 73 is configured to have dimensions which ensure that it protrudes from its respective groove. Accordingly, the seal(s) 73 each protrude above the surface 72 of the test handler 7. The seal(s) 73 facilitate the application of a vacuum to the tile, as will be described in more detail later, and thus is often referred to as a vacuum seal.

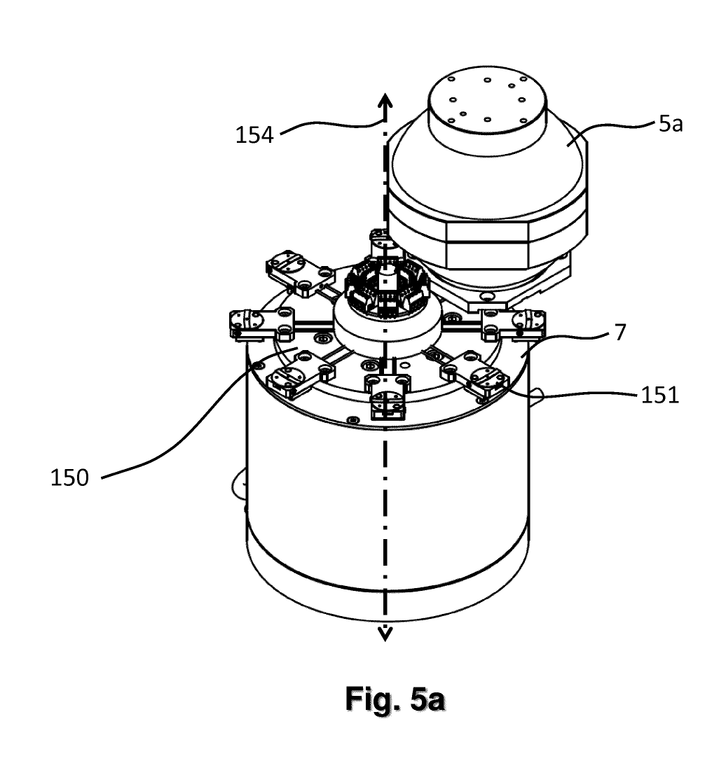

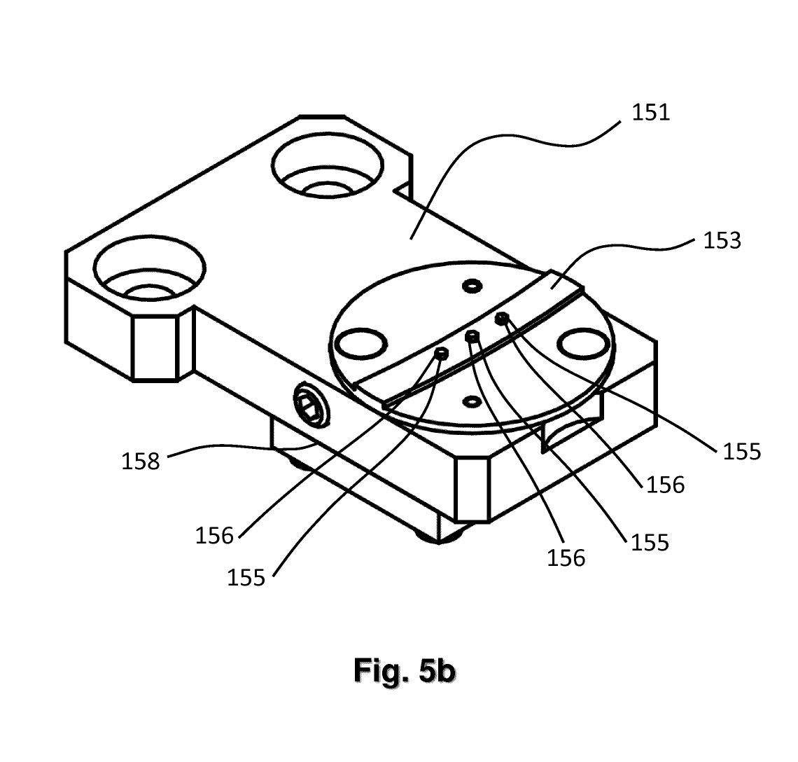

It should be understood that the carrier 7 provided in the assembly of the present invention may take any suitable configuration and is not limited to being in the form of a test handler 7 with plunger head 7a. FIG. 5a provides a perspective view of another exemplary configuration for the carrier 7. The carrier 7 shown in FIG. 5 comprises a rotary table 150 having a plurality of nests 151. The rotary table 150 is configured so that it can rotate about a rotary axis 154. The rotary table 150 is positioned below the light integrating sphere 5 in the assembly and is arranged such that a nest 151 is directly aligned with the inlet window 51 of the light integrating sphere 5a. The rotary table 150 can be selectively rotated about the rotary axis 154 to move another of the nests 151 so that it directly aligned with the inlet window 51 of the light integrating sphere 5a.

FIG. 5b provides a perspective view of a nest 151. The nest 151 comprises a flat surface 153 on which a group of devices can be supported. The nest 151 is configured such that no part of the nest 151 extends above the plane of the flat surface 153. In this embodiment the flat surface 153 on which the devices can be supported defines the top surface or more specifically defines the uppermost surface of the nest 151. This ensures that no part of the nest 153 will obstruct light emitted by the devices which are positioned on the flat surface 153. Also the flat surface allows any sized device to be supported on the nest, so the carrier is not limited to carry devices of specific dimensions. This is in contrast to nests used in the prior art which comprise cavities defined by a base and walls, and wherein the devices are supported on the base of those cavities, and wherein the walls of the cavities extend above the base. Disadvantageously in the nests of the prior art the walls of the cavities will obstruct light emitted by a light emitting device located in the cavity so that some of the light emitted will not be received into the light integrating sphere 5a during testing. In the present invention since the nest is without a structure which extends above the plane of the flat surface on which the device is supported, no part of the nest will obstruct the emission of light from the light emitting device, so that all light emitted will be received into the light integrating sphere 5a during testing.

The nest further comprises designated areas 155 of the flat surface 153 in which light emitting devices can be positioned. Within each of these areas 155 there is provide a vacuum opening 156 (which is covered by the light emitting devices in FIG. 5b). Each of the vacuum openings 156 is fluidly connected to a vacuum generating means so that a vacuum can be applied to devices which are positioned in the designated areas 155 of the flat surface 153.

Each of the designated areas 155 comprise electrical contacts (which is covered by the light emitting devices in FIG. 5b). The electrical contacts of each of the designated area 155 is electrically connected to a respective light emitting device which is positioned at that area 155.

Electrical contact pins 79 of a contact unit 75 which is electrically connected to a control and parameter measuring unit 3 can be moved to contact the electrical contacts provided in the nest 151; and the electrical signals which implement the electrical and/or optical testing can be sent by the control and parameter measuring unit 3 to the devices supported on the flat surface 153 of the nest.

It will be understood that the nest 151 may have any one or more of the features of the test handler 7 shown in FIGS. 1-3.

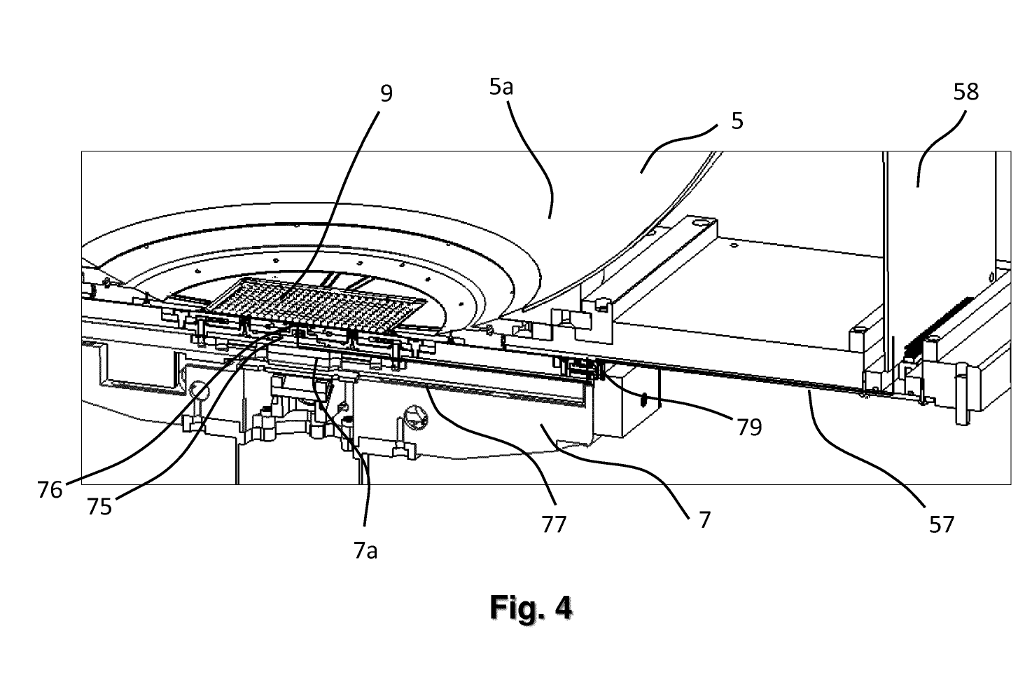

FIG. 4 shows, in a synoptical illustration combining a partial view of FIG. 2 and a signal flow diagram, how in the electrical testing signals from the devices on the test array 9 are routed through the plunger head 7a or electrical contact pins, respectively, and the integrating sphere unit 5. Electrical contact pins (embodied typically as so-called pogo pins) 76 in the contactor unit 75 collect the signals and rout them through leads provided in the contactor unit, including a lead arrangement on a PCB 77, to output contacts 79 of the plunger head. There, the measuring signals are handed-over to the integrating sphere unit 5, more specifically to a PCB 57 of that component of the test arrangement. Output contacts (not shown) of the PCB 57 are connected to a Multiplexer 58 which in turn is connected to the test control and parameter measuring unit 3 (FIG. 1). The multiplexer 58 is used to pass electrical signals which implement said optical testing to each of the test contacts sequentially.

In an embodiment the multiplexer 58 can comprise four input channels which can receive command signals from the control and parameter measuring unit 3; and for each input channel there is provided a group of eight output channels each of which is electrically connected to a series of eight electrical contact pins 79 of the contact unit 75 which can output electrical testing electrical signals which implement electrical tests. In this embodiment each device comprises a pair of electrical contact pins 79, therefore two multiplexers 58 (first and second multiplexers 58) are provided to allow electrical testing of a group of eight devices simultaneous. During electrical testing each respective group of eight output channels of each multiplexer 58 is addressed consecutively, so that electrical signals which implement electrical tests are passed consecutively to groups of eight devices (each device in the group of eight receiving simultaneously the electrical signals). For example in order to perform electrical testing of 24 devices electrical testing is performed on three groups of eight devices (first, second and third group of eight devices); a first group of eight output channels of a first multiplexer are addressed (via the first input channel) to allow electrical testing electrical signals which implement electrical tests to be passed simultaneously to four devices in the first group of eight device (i.e. four pairs of electrical contact pins 79 channels) simultaneously a first group of eight output channels of a second multiplexer are addressed (via the first input channel) to allow electrical testing electrical signals which implement electrical tests to be passed simultaneously to the remaining four devices in the first group of eight device (i.e. four pairs of electrical contact pins 79 channels). To test the second group of eight devices a second group of eight output channels of a first multiplexer are addressed (via the second input channel) to allow electrical testing electrical signals which implement electrical tests to be passed simultaneously to four devices in the second group of eight device (i.e. four pairs of electrical contact pins 79 channels) simultaneously a second group of eight output channels of a second multiplexer are addressed (via the first input channel) to allow electrical testing electrical signals which implement electrical tests to be passed simultaneously to the remaining four devices in that second group (i.e. four pairs of electrical contact pins 79 channels). To test the final eight devices out of the ‘24’ device, a third group of eight output channels of a first multiplexer are addressed (via the second input channel) to allow electrical testing electrical signals which implement electrical tests to be passed simultaneously to four devices in the third group of eight (i.e. four pairs of electrical contact pins 79 channels) simultaneously a second group of eight output channels of a second multiplexer are addressed (via the first input channel) to allow electrical testing electrical signals which implement electrical tests to be passed simultaneously to the remaining four devices in the third group (i.e. four pairs of electrical contact pins 79 channels). Thus all ‘24’ device will have undergone electrical testing. It will be understood that multiplexer 58 may have any suitable configuration e.g. it may have any number of input and output channels; it will also be understood that any number of multiplexers may be provided (i.e. the present invention is not limited to requiring two multiplexers).

According to an exemplary contacting and measuring scheme of a light-emitting device panel, the electrical test starts with contacting all devices on a first row of the panel, e.g. 24 devices. Then, the devices on this first row are electrically tested, sequentially e.g. in three groups each comprising 8 devices. After the electrical test sequence, the arrangement is switched to start the sequential optical tests, driving all devices of the first row individually and measuring the individual optical parameters of the respective device. Once the electrical and optical testing of all devices of the first row is terminated, the arrangement is mechanically indexed, i.e. the row contactor unit shifted by one row distance and the second row contacted. Then the whole procedure is repeated for the second row, and so forth, until all devices in all rows have been tested.

The above-mentioned assembly can be used to perform a method according to the present invention:

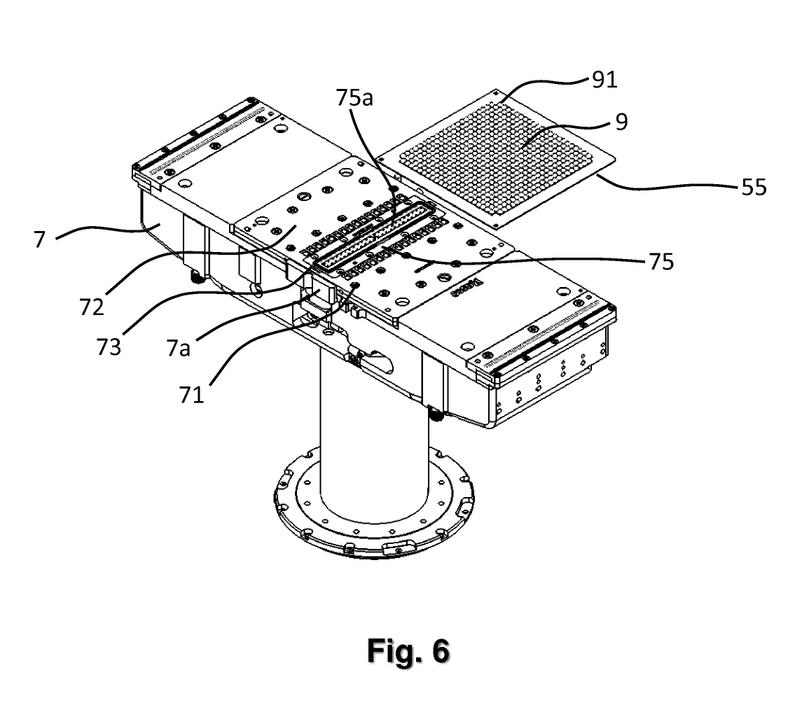

A plurality of light-emitting devices 91 are provided on a tile 55 to form a test array 9. The tile 55 is then arranged onto the surface 72 of the plunger head 7a of the test handler 7 as is illustrated in FIG. 6.

After the tile 55 has been arranged onto the surface 72, the vacuum generator, which is in fluid communication with the vacuum openings 71, is then operated so that a vacuum is applied to the tile 55 so that the tile 55 (and test array 9) is held on the surface 72 of the plunger head 7a.

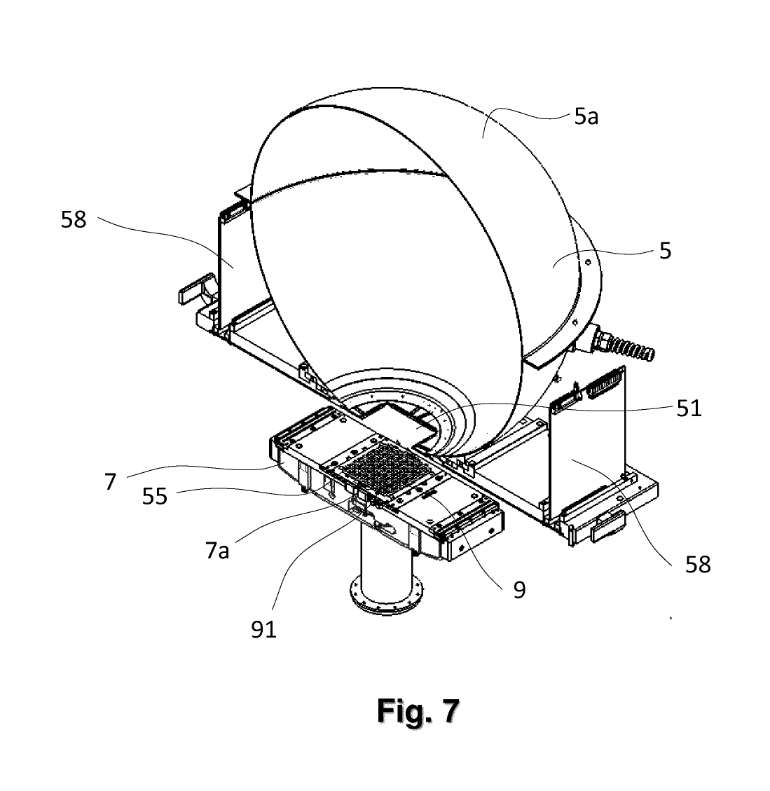

Next the test handler 7 is moved so that it is adjacent the inlet window 51 of the light integrating sphere 5, as shown in FIG. 7.

The plunger head 7a it then extended from the test handler 7 to deliver the light emitting devices 91 to the test position. Specifically the plunger head 7a moves the tile 55 to a position where the light emitting devices 91 can emit light into the light integrating sphere 5a and the tile 55 optically seals the inlet window 51 so that the light integrating sphere 5a is optically sealed from ambient light. In the test position each of the light emitting device 91 in the test array 9 will be positioned such that they extend above the inlets window 51 into the integrating sphere so that the surface which define the inlets window 51 will not obstruct light emitted by the light emitting device 91 (specifically in the test position each of the light emitting device 91 in the test array 9 will be positioned such that they extend above the surface which defines the inlet window 51).

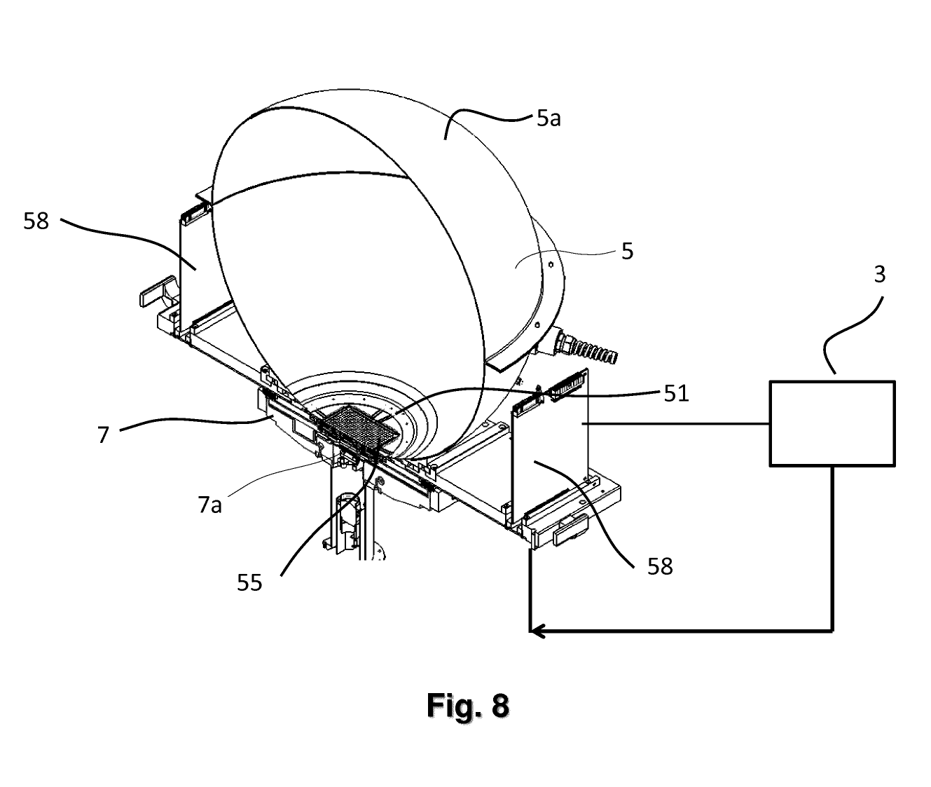

Once test handler 7 has delivered the light emitting devices 91 to the test position the docking means in the light integrating sphere 5a holds the tile 55, so that the light emitting devices 91 are maintained in the test position. Once the docking means in the light integrating sphere 5a holds the tile 55 the vacuum generating means which provided the vacuum at the vacuum opening 71 is turned off so that the tile 55 is held exclusively by the docking means. FIG. 8 illustrates the light emitting devices 91 having been move to the test position; and wherein the tile 55 has been positioned to optically seal the inlet window 51 of the light integrating sphere 5a and is held in position by the docking means in the light integrating sphere 5a.

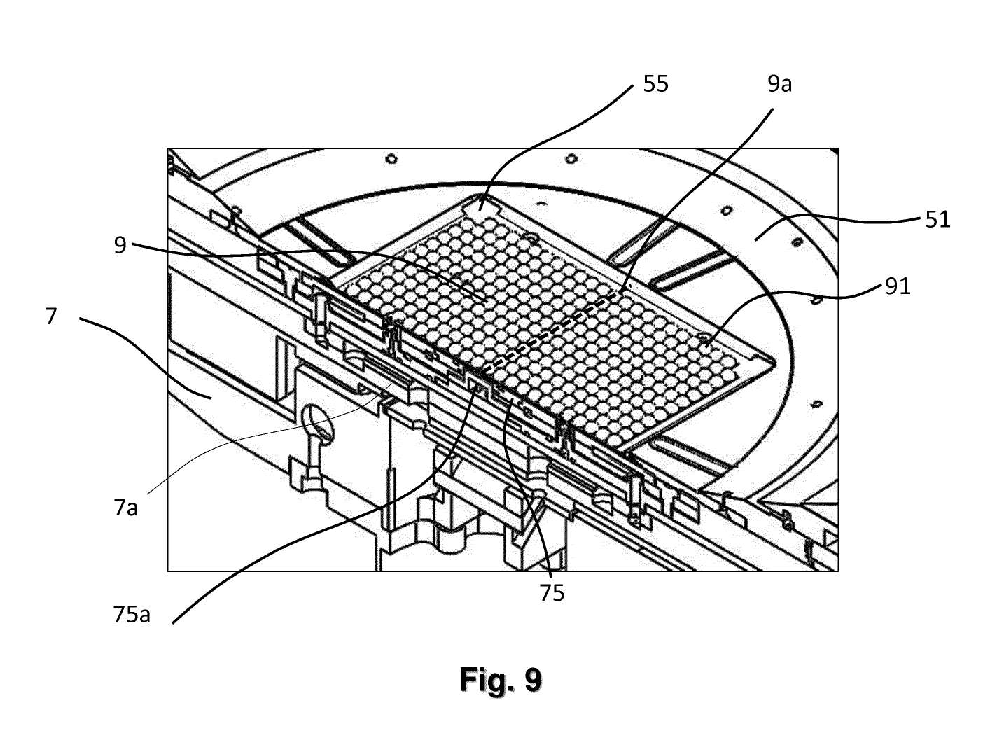

The test handler 7 is then moved so that the contact sockets 75a in the contact unit 75 on the plunger head 7a are aligned with electrical contacts of the light emitting devices in a first row of the test array 9. FIG. 9 illustrates the test handler 7 after it has been moved so that the contact sockets 75a in the contact unit 75 are aligned with electrical contacts of the light emitting devices 91 in a first row 9a of the test array 9.

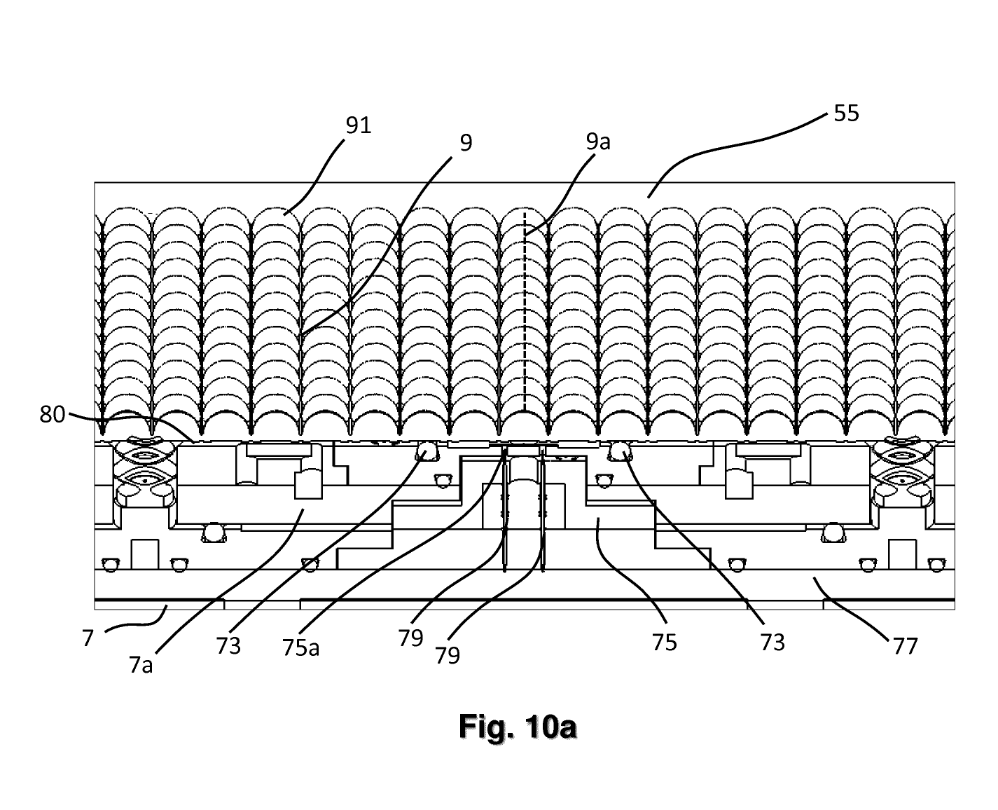

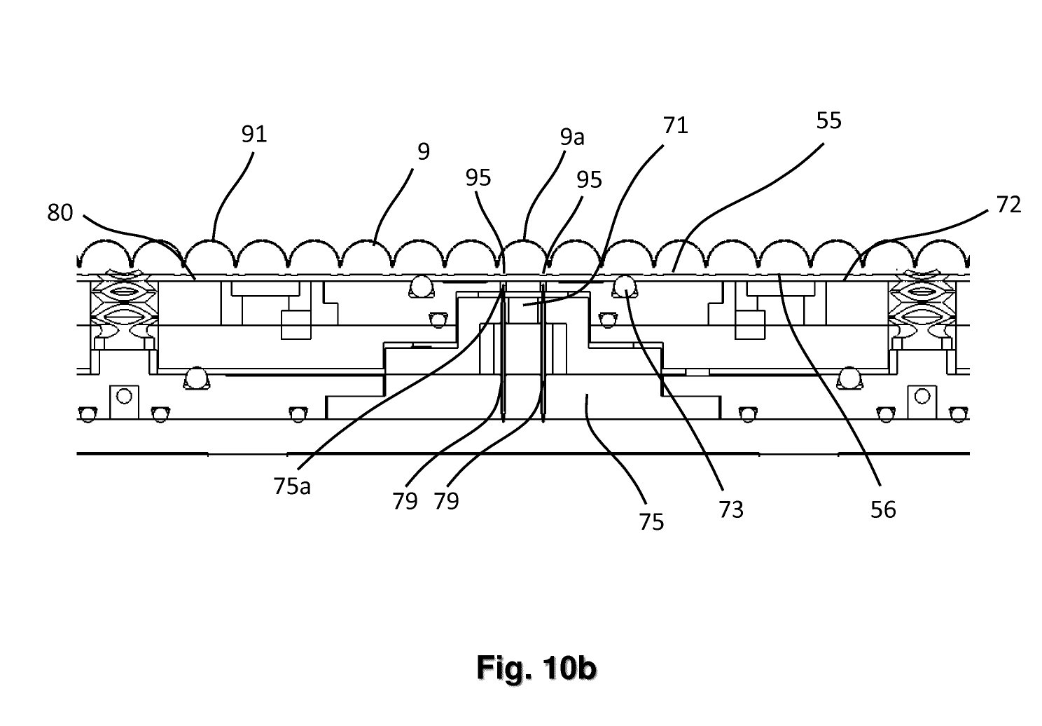

While maintaining the contact sockets 75a in alignment with electrical contacts of the light emitting devices 91 in a first row 9a of the test array 9, the test handler 7 is then moved so that the seals 73 on the surface 72 of the plunger head 7a abut the bottom tile 55. FIGS. 10a and 10b illustrate the test handler 7 after having been moved so that the seals 73 on the surface 72 of the plunger head 7a abut the bottom tile 55. The seals 73 advantageously provide for damping as the test handler 7 is moved to abut the tile 55. The seals 73 further provide for an air gap 80 between the surface 72 of the plunger head 7a and the tile 55 after abutment. As can be best seen from FIG. 10b the contact sockets 75a in the contact unit 75 are aligned with electrical contacts 95 of the light emitting devices 91 in a row 9a of the test array 9.

FIGS. 10a & 10b also illustrate the electrical contact pins 79 of the contact unit 75. Although the only two electrical contact pins 79 are visible in the Figures, it will be understood that a plurality of electrical contact pins 79 are provided corresponding to the plurality of contact sockets 75a illustrated in FIG. 6. The plurality of electrical contact pins 79 can be selectively moved to protrude from the plurality of contact socket 75a so that they extend above the surface 72 of the plunger head 7a. Preferably the number of light emitting devices 91 provided in each row (or column) of the test array 9 is such that the sum of the number of electrical contacts 95 of all the light emitting devices 91 in the row 9a is equal to the number of electrical contact pins 79 provided in the contact unit 75. In another embodiment two electrical contact pins 79 contact each of the electrical contacts 95 of each light emitting device 91 in a row of the test array, according in there the number of electrical contact pins 79 is twice the sum of all the electrical contacts 95 of all the light emitting devices 91 in a row 9a. It should be understood that any number of electrical contact pins 79 may be provided, and that any number of light emitting devices 91 may be provided in a row 9a, and the light emitting devices 91 may each have any number of electrical contacts 95.

After the test handler 7 has been moved so that the seal 73 on the surface 72 of the plunger head 7a abut the tile 55, the vacuum generator, which is in fluid communication with the vacuum opening 71 on the plunger head 7a, is then operated so that a vacuum is applied to an undersurface 56 of the tile 55 so that the tile 55 is moved to compresses the seal 73 and come substantially in contact with the surface 72 of the plunger head 7a. The seals aid to confine the vacuum to within the air gap 80, thus facilitating the application of the vacuum to the tile 55. Simultaneously, as the vacuum is applied to the undersurface 56 of the tile 55, the electrical contact pins 79 of the contact unit 75 are moved to protrude from the plurality of contact socket 75a to extend above the surface 72 of the plunger head 7a, and mechanically contact respective electrical contacts 95 of some or all of the light emitting devices 91 in row 9a. In this example the electrical contact pins 79 of the contact unit 75 are moved to protrude from the plurality of contact socket 75a to extend above the surface 72 of the plunger head 7a, and mechanically contact respective electrical contacts 95 of a predefined number of the light emitting devices 91 in row 9a; said ‘predefined number of the light emitting devices 91’ will be referred to hereafter as ‘group 19 of light emitting devices 91’. In this example each row in the test array 9 (including first row 9a) comprises 24 light emitting device 91; a group 19 of light emitting devices 91 comprises eight light emitting devices 91, therefore each row in the test array 9 comprises 3 groups 19. However it will be understood that the test array 9 and/or the rows of the test array could comprise any number devices; likewise the group 19 could comprise any number of light emitting devices 91.

It is pointed out that the plurality of electrical contact pins 79 in the contact unit 75 are simultaneously moved so that they mechanically contact all of the electrical contacts 95 of all the light emitting devices 91 in the group 19 at the same time. In other words, each of the plurality of electrical contact pins 79 mechanically contact a single respective electrical contact 95 of a light emitting device 91 in the group 19; all of the plurality of electrical contact pins 95 are moved simultaneously to mechanically contact a respective electrical contact 95. Accordingly at this stage all electrical contacts 95 of all the light emitting devices 91 in the group 19 are in mechanical contact with a respective electrical contact pin 79 of the contact unit 75. In another embodiment all electrical contacts 95 of all the light emitting devices 91 in the group 19 are each in mechanical contact with a two electrical contact pins 79 of the contact unit 75 i.e. there are two electrical contact pins 79 for each electrical contact 95 of a light emitting device 91.

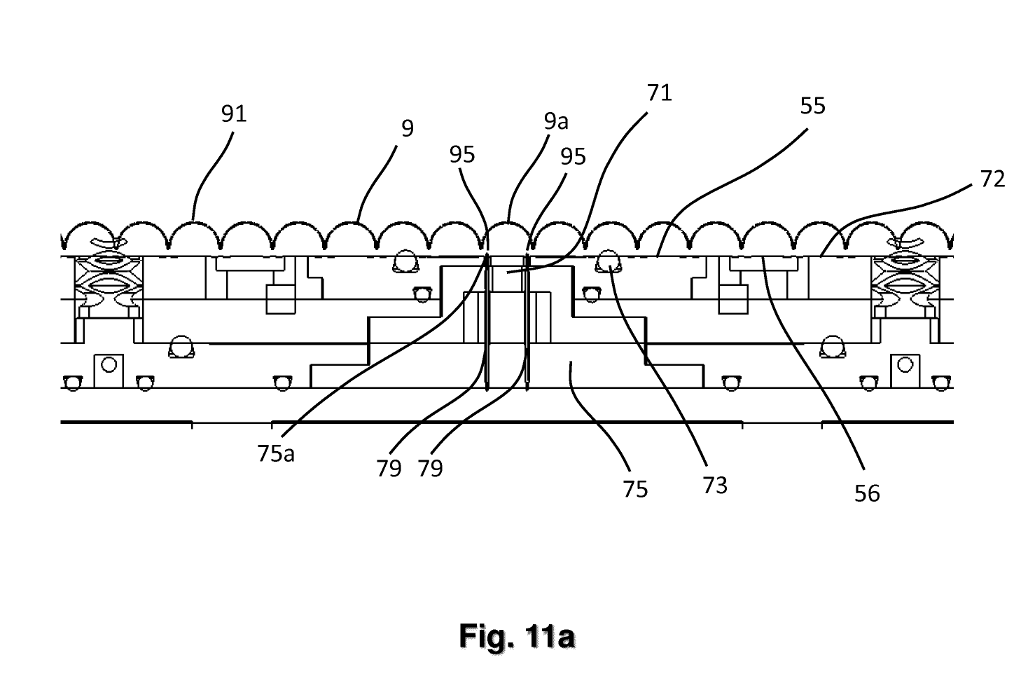

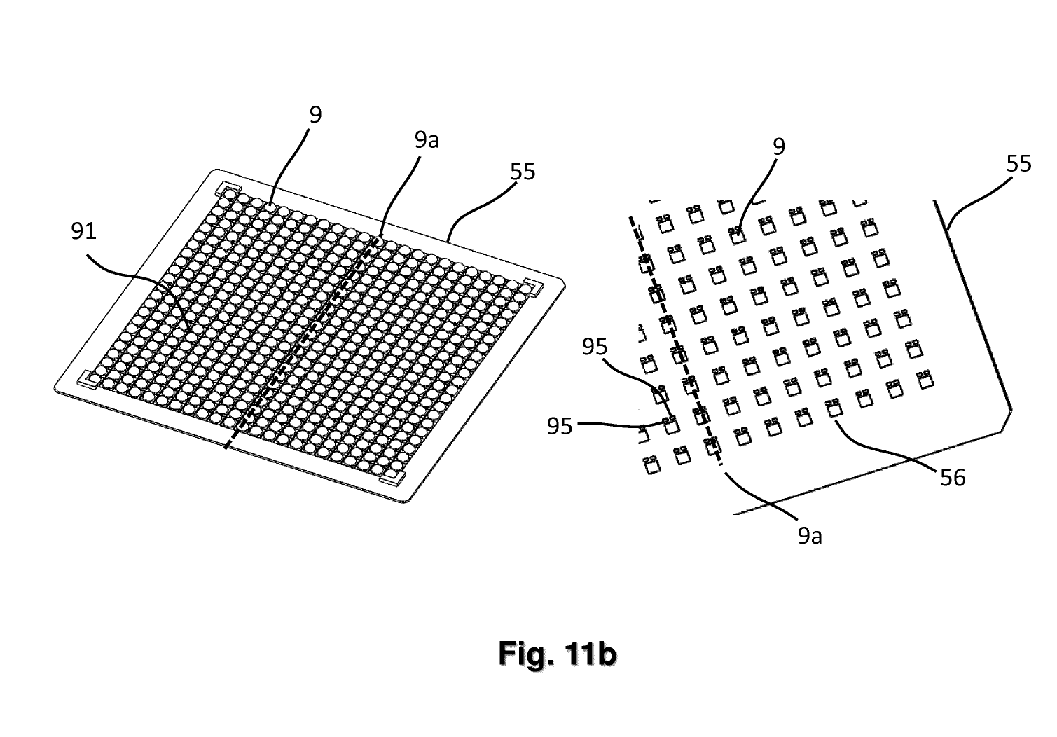

FIG. 11a illustrates the tile 55 after the vacuum is applied to its undersurface 56 via the vacuum opening 71 on the surface 72 of the plunger head 7a; and, simultaneous to the application of vacuum, the electrical contact pins 79 of the contact unit 75 having been moved to protrude from the plurality of contact socket 75a, to extend above the surface 72 of the plunger head 7a, to simultaneously mechanically contact all electrical contacts 95 of the light emitting devices 91 in the group 19.

It should be understood that the tile 55 used in the present invention is configured such that the electrical contacts 95 of light emitting devices 91 supported on the tile 55 remain exposed to allow those electrical contacts 95 to be contacted by the electrical contact pins 79 provided in the contact unit 75 of the plunger head 7a. FIG. 11b shows a perspective view of a tile 55 on which device 91 are supported; and shows part of an undersurface 56 of the tile 55 where the electrical contacts 95 of light emitting devices 91 are exposed. Having the electrical contacts 95 of light emitting devices 91 exposed at the undersurface 56 of the tile allows the electrical contact pins 79 of the contact unit 75 to electrically contact the electrical contacts 95 of light emitting devices 91. It can also be seen that each device 91 has two electrical contacts 95; however each device 91 can have any number of electrical contacts 95.

It will be understood that the test control and parameter measuring unit 3 may initiate some or all of the above mentioned method steps.

Once electrical contact pins 79 of the contact unit 75 mechanically contact all electrical contacts 95 of the light emitting devices 91 in the group 19 the electrical and optical testing of the light emitting devices 91 in the group 19 can commence. Test control and parameter measuring unit 3 is responsible for carrying out the electrical and optical testing of the light emitting devices 91. In this embodiment the electrical testing of the devices in the group 19 is performed prior to optical testing; the advantage of carrying out the electrical and optical testing in this order is that by doing electrical testing first one can forgo or skip unnecessary optical tests of components which have already fails electrical testing. Electrical testing is carried on the group of components in parallel so that all of the groups of components are electrically tested simultaneously. Optical testing on the other hand is carried out consecutively on each of the individual components in the group and therefore is time consuming. By doing the electrical testing first the system can optically test only those components in the group which have passed the electrically testing therefore allowing more efficient use of resources as optical testing is not performed on those components in the group which are anyway destined to be rejected for failing the electrical testing. For example if there are eight devices in a group, consider that it takes 150 ms to perform electrical testing of all eight components in the group simultaneously and 20 ms to perform optical testing of one of the eight components; in the present invention if for example four of the eight component fail the electrical testing then optical testing is performed on only the four of the eight components which passed the electrical testing. There is thus a time saving of 80 ms (4*20 ms) which would otherwise have been used to test the four components which failed the electrical testing. Accordingly in summary the advantage of carrying out the electrical and optical testing in this order is that time saving and more efficient use of resources is achieved since optically testing can be confined only to those components which have successfully passed the electrical testing.

The electrical testing of all the light emitting devices 91 in the group 19 is carried out in parallel, so that electrical parameters of each of the light emitting devices 91 in the group 19 can be determined; and optical testing of all the light emitting devices 91 in the group 19 is carried out in a sequential device-by-device manner, so that optical parameters of each of the devices in the group can be determined.

To perform electrical testing the test control and parameter measuring unit 3 sends electrical test signals which implement the necessary electrical testing in the light emitting devices 91 in the group 19. The electrical test signals are sent from the test control and parameter measuring unit 3 to all of the electrical contact pins 79 in the contact unit 75 simultaneously, so that the test signals reach all electrical contacts 95 of all the light emitting devices 91 in the group 19 simultaneously. This enables the simultaneous electrical testing of all the light emitting devices 91 in the group 19 to be performed. The electrical responses of each light emitting device 91 to the electrical test signals are sent back to the test control and parameter measuring unit 3 where they are analyzed and processed by the test control and parameter measuring unit 3 to determine how each of the each light emitting device 91 of the group 19 performed in the electrical test.

After electrical testing of the light emitting devices 91 of the group 19 has been performed sequential optical testing of each light emitting device 91 of the group 19, device-by-device, can begin.

Optical test signals are sent from the test control and parameter measuring unit 3 only to electrical contact pins 79 in the contact unit 75 which mechanically contact the electrical contacts 95 of a single light emitting device 91 in the group 19 only, so that the electrical contacts 95 of that single light emitting device 91 in the group 19 only receives the optical test signals. When that single light emitting device 91 receives the optical test signals the single light emitting device 91 emits light into the light integrating sphere 5a. The emitted light is collected by the light integrating sphere and values representing the amount and direction of the light collected is generated and sent to the test control and parameter measuring unit 3 where they are analyzed and processed by the test control and parameter measuring unit 3 to determine optical parameters of that single light emitting device 91. These steps are performed for each of the light emitting devices 91 in the group 19 until all the light emitting devices 19 in the group have been individually optically tested independent of one another i.e. each of the light emitting devices 91 in the group 19 is optically tested at a different time. Thus after optical testing of the devices 91 in the group 91 and optical parameters of each of the device 91 will have been determined.

In one embodiment a multiplex is provided in the test arrangement 1 which has a plurality of outputs each of which is electrically connected to a respective electrical contact pin 79 in the contact unit 75 and an input which is electrically connected to the test control and parameter measuring unit 3. The multiplexer is used to selectively address each of the electrical contact pins 79 in the contact unit 75 and thus is operable to send the optical test signals to a selected light emitting device 91 in the group 19. For example, if the first light emitting device is to be optically tested; then the optical test signals are sent from the test control and parameter measuring unit 3 to the multiplexer; the test control and parameter measuring unit 3 then controls the multiplexer so that the optical test signals are passed to the output of the multiplexer which is electrically connected to the electrical contact pins 79 in the contact unit 75 which mechanically contact the electrical contacts 95 of the first light emitting device 91 in the group 19, so that the electrical contacts 95 of the first light emitting device 91 in the group 19 only receives the optical test signals. The test control and parameter measuring unit 3 controls the multiplexer so that optical test signals are sent, to each light emitting device 91 in the group 19, so that each of the light emitting devices 91 in the group 19 can be individually optically tested independently of the other devices 91 in the group 19.

It will be understood that any electrical testing and optical testing may be carried out in the present invention; the electrical testing may involve testing for any electrical parameters of the light emitting devices 91 and the optical testing may involve testing for any optical parameters of the light emitting devices 91. The electrical testing typically involve performing electrical tests which are designed to determine if the device is functioning as expected, if the device is mechanically functional (e.g. that the device was fabricated without flaws) and to determine if the part can operate under normal conditions. For example the devices will typically be LEDs each of which have two pads (i.e. two electrical contacts); to perform electrical testing the electrical contact pins 79 in the contact unit 75 define positive and negative probes which are arranged to electrically contact the two pads of respective LEDs. Once the LED pads are contacted by the probes the test control and parameter measuring unit 3 will initiate a predefined current or voltage to pass through the LED and this will cause the LED to light up. The test control and parameter measuring unit 3 will measure the voltage in and voltage out of each respective LED and can calculate the resistance of that LED. Knowing all of these values the test control and parameter measuring unit 3 can determine if each respective LED was manufactured properly, for example: If the test control and parameter measuring unit 3 measures a voltage across the LED and the voltage in is a known controlled input voltage but the voltage out is at 0, then the test control and parameter measuring unit 3 would indicate that the LED is not functioning properly and the mechanical connection inside the LED has failed and the LED will not light up; therefore the LED will be deemed to have failed the electrical test. If on the other hand the test control and parameter measuring unit 3 measures voltage out to be exactly the same as voltage in then the test control and parameter measuring unit 3 will determine that the LED has a short or that the two electrical contacts 95 are electrically connected or touching, and therefore the LED will be deemed to have failed the electrical test. Optical testing is performed on those components which have passed the electrical testing. The optical testing may involve applying a known voltage and current to the LED's in the group respectively so that each LED consecutively lights up inside the sphere. The properties of the light integrating sphere collect the light emitted, and then using a spectrometer or spectroradiometer test control and parameter measuring unit 3 then extracts predefined properties of the light collected by light integrating sphere and compares those extracted properties to corresponding properties of a reference light emitted by an reference LED (which provides optimal LED performance). After the comparison the LED under test would be categorized according to extracted properties.

Once all the light emitting devices 91 in the group 19 have been electrically and optically tested, the test handler 7 is then moved so that the next group of eight light emitting devices in the first row 9a can be electrically and optically tested in the same manner as described above. This is repeated until all the groups of light emitting devices 91 in the first row of the test array 9 are electrically and optically tested; after which the test handler 7 is then moved so that the groups 19 in the other remaining rows of the test array 9 can be electrically and optically tested in the same manner as described above.

Importantly in this embodiment the test array 9 remains in the same single fixed position during the optical testing of all the light emitting devices 91 in the test array 9. In this embodiment the test array 9 also remains in the same single fixed position during the electrical testing of all the light emitting devices 91 in the test array 9. Thus the test array is never moved from its original test position during electrical and optical testing of all devices 91 in the test array 9. Thus the optical testing and electrical testing of all the light emitting devices in the test array 9 is performed without moving the test array 9 from the initial test position to which it was initially brought. Since each light emitting device 91 occupies a different position in the test array 9 and since the test array 9 remains in a single fixed position during the optical testing, each individual light emitting device will be located in a different position with respect to the center of the light integrating sphere 5a when optical testing is performed. The differing positions with respect to the center of the light integrating sphere 5a will mean that different parts of the light integrating sphere 5a will receive more light than other parts depending on the position of the light emitting device 91 which is being tested.

In order to address this test control and parameter measuring unit 3 is configured to perform a post-processing of the measured optical parameters for each light emitting device according to the individual positions of that device relative to the center of the integrating sphere. In order to post process the optical parameters, offsets corresponding to the position of the respective light emitting device relative to the center of the integrating sphere, are added to the measured optical parameters. For example a look-up-table having a list of positions for devices in the test array relative to center of the light integrating sphere 5a and a corresponding offset for each position entry in the look-up-table; each offset is a predetermined value which is to be added to optical parameters measured during the optical testing to compensate for the position of device being offset from the center of the light integrating sphere. Thus when optical testing of a device have been performed the test control and parameter measuring unit 3 determines the position of that light emitting device relative to the center of the integrating sphere; the test control and parameter measuring unit 3 then retrieves the offset from the look-up-table which corresponds to the determined position and the retrieved offset is added to optical parameters measured for that device so as to compensate for the position of device being offset from the center of the light integrating sphere. This is done for each of the devices in the group 19 (and each device of subsequently optically tested groups; and ultimately for all devices in the test array 9); accordingly optical testing of all devices in a whole test array can be tested without having to move the tray within the light integrating sphere 5a.

The look-up-table is formed during a calibration step which involves positioning light emitting devices which have known optical parameters, at each of the positions relative to the center of the integrating sphere where light emitting devices under test are due to be positioned. The positions of each of the light emitting devices is noted in the look-up-table. The optical testing is then performed consecutively on each of the light emitting devices, for each device emitted light is collected by the light integrating sphere 5a; values representing the amount and direction of the light collected is generated and sent to the test control and parameter measuring unit 3 where they are analyzed and processed by the test control and parameter measuring unit 3 to determine measured optical parameters of each individual light emitting device 91. For each device the determined measured optical parameters are then compared to the known optical parameters for that device, and for each device the difference between the determined measured optical parameters for that device and the known optical parameters for that device defines the offset which is to be added measured optical parameters to compensate for the position of device being offset from the center of the light integrating sphere.

Preferably the number of said light emitting devices which have known optical parameters correspond to the number of devices which are due to be in the test array 9; and preferably be arranged on a tile identical to the tile on which the test array is due to be positioned, in the same arrangement as the arrangement of the devices which are due to be in the test array 9. However in the event that the number and/or arrangement of the devices in the test array 9 are different to the number and/or arrangement of said light emitting devices which have known optical parameters used in the calibration step then interpolation of the offset values in the look-up-table can be used to determine the values of the offsets which is to be added measured optical parameters to compensate for the position of devices being offset from the center of the light integrating sphere. For example: if said light emitting devices which have known optical parameters were arranged in a 20×20 matrix on a tile (i.e. 20 devices along each column and 20 devices along each row) (at for example 4 mm pitch from LED to LED in a line) then the look-up-table would have 400 offset entries corresponding to each of the 400 different positions relative to the center of the light integrating sphere, of the 400 light emitting devices on the tile. If on the other hand the devices which are to undergo optical testing are arranged in a 40×40 matrix on a tile (i.e. 40 devices along each column and 40 devices along each row)(at for example 2 mm pitch) then there would be 800 devices having 800 different positions relative to the center of the light integrating sphere; the offset to apply to each of the measured optical parameters for 400 of those devices can be read directly from the look-up-table based on their respective positions relative to the center of the light integrating sphere, and for each of the remaining 400 devices linear interpolation of the offset values in the look-up-table, according to their respective positions relative to the center of the light integrating sphere, can be used to calculate the offset which is to be added to their respective measured optical parameters to compensate for their respective positions being offset from the center of the light integrating sphere.

In another embodiment no interpolation is performed, rather for each device the test control and parameter measuring unit 3 identifies the position entry in the look-up-table which is closest to the position of the device and the offset which corresponds to the identified position is added to the measured optical parameter for that device to compensate for the position of that device being offset from the center of the light integrating sphere.

In yet another embodiment no offset is added to the measured optical parameter devices to compensate for the position of that device being offset from the center of the light integrating sphere. This may be the case when the offset of the devices with respect to the center of the light integrating sphere has a negligible effect on the optical measurements; accordingly the optical measurements do not need to be adjusted to compensation for the offset position of the devices. One example would be when, for example, when each of the devices of the test array are within 5 mm of the center of the light integrating sphere; in this example each of the devices in the test array are close enough to the center of the light integrating sphere that its offset from the center of the light integrating sphere has a negligible effect on the measured optical parameters.

As mentioned the light emitting devices which have known optical parameters, which are used in the calibration step are arranged on a tile. For the calibration step the tile should be positioned at a predefined position in the light integrating sphere 5a; the predefined position will also be the position in which the tile on which devices to be tested will be arranged when the test array 9 are in the testing position. A camera is provided on the plunger head 7a which can be used to position the tile with light emitting devices which have known optical parameters into the predefined position in the light integrating sphere 5a. The light integrating sphere 5a comprises fiducials which indicate the centre of the light integrating sphere 5a the tile with light emitting devices which have known optical parameters also comprise fiducials which which indicate the centre of the tile. The camera first captures a first image of the fiducials on the light integrating sphere, and determines from the first image the position of the centre of the light integrating sphere 5a within a predefined reference frame; next the camera captures a second image of the fiducials on the tile, and determines from the second image the position of the centre of the tile within the predefined reference frame. When both positions are known it can be determined how the tile should be moved so that the tiles centre is aligned with the centre of the light integrating sphere 5a.

During testing the position of the centre of the light integrating sphere 5a within the predefined frame of is typically determined only once. The positions of different tiles which carry devices to be tested, within the predefined frame is determined each time a new tile is presented which has new devices for test, so that the tiles position relative to the centre of the light integrating sphere 5a can be determined (which enables determining how the tile should be moved to bring it to the centre of the light integrating sphere 5a).

Preferably the dimensions of the tile on which the devices to be tested are provided are predefined. The predefined tile dimensions can be used to determine the position of the devices relative to the center of the light integrating sphere 5a. The user must enter in the size of the device, the x pitch (device to device distance), the y pitch (device to device distance), the number of devices in a column and in a row, and the xy distance of the two fiducials from the center of the LED device pattern. Knowing these values the exact position of each device on a tile relative to the centre of the light integrating sphere can be calculated so that the appropriate offset to add to the measure optical parameters to compensate for the position of device, can be retrieved from the look-up-table.

The above example illustrates an assembly according to the present invention, which comprises a carrier 7 in the form of a test handler 7, being used to perform a method according to the present invention. It will be understood that an assembly according to the present invention, which comprises a carrier 7 in the form illustrated in FIG. 5 above, may also be used to perform a method according to the present invention: In this case electrical and optical testing is performed in the same manner as above, along with the optional post processing of the optical parameters. However the manner in which the light emitting devices 91 are moved to the test position is different:

The rotary table is first rotated about the rotary axis 154 so as to move one of the nests 151 into a loading area where light emitting devices 91 can be loaded onto the flat surface 153 of that nest 151. Once the nest 151 has been moved to the loading area the vacuum generating means which is fluidly connected with the vacuum openings 156 of that nest 151 is then operated to provide a vacuum at the flat surface 153 of the nest 151.

Light emitting devices 91 are loaded onto each of the designated areas 155 on flat surface 153 of a nest 151 on the rotary table 150. The plurality of light emitting devices 91 located on the flat surface 153 of the nest constitute a group 19 of light emitting devices. When a light emitting device 91 is positioned at a designated area 155 the vacuum will hold that device in the designated area 155 in which is was placed; furthermore the electrical contacts of the light emitting device 91 will contact the electrical contact platforms 158 of that designated area 155.

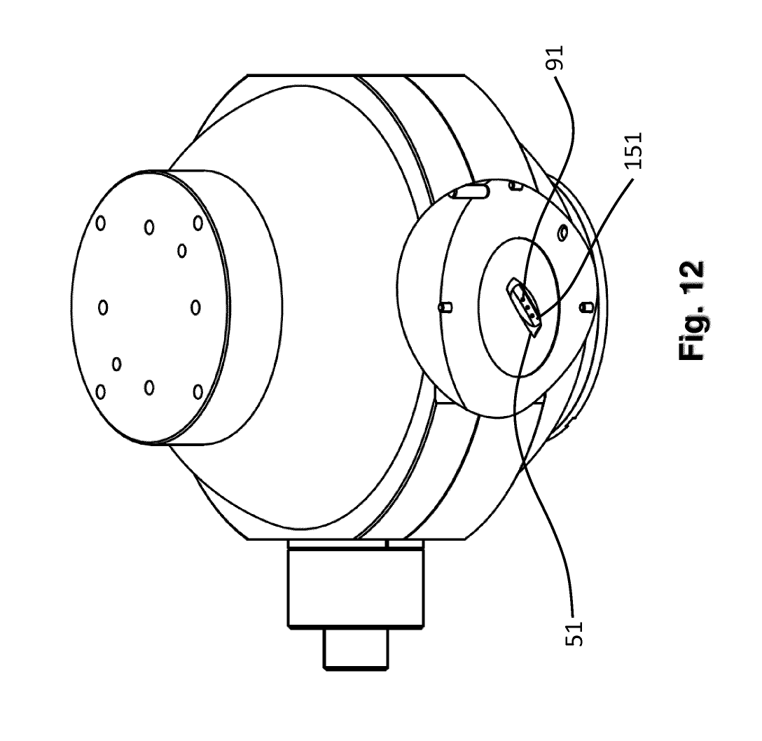

Next the rotary table 150 is rotated about the rotary axis 154 to move the nest 151 on which light emitting device 91 have been loaded, so that the nest 151 is aligned with the inlet window 51. When the nest 151 has been moved so that the nest 151 is aligned with the inlet window 51 the light emitting devices 91 will be in the test position. When the nest 151 is aligned with the inlet window 51 the light emitting devices 91 will extend above an inner surface 135 of the light integrating sphere 5a. It should be noted that in this embodiment no sealing ring 53 is provided in the assembly and the inlet window 51 is defined in light integrating sphere 5a. FIG. 12 illustrates the assembly after the rotary table 150 has been rotated about the rotary axis 154 to move the nest 151 on which light emitting device 91 have been loaded, so that the nest 151 is aligned with the inlet window 51. In FIG. 12 a part-cut-away portion of the integrating sphere is provided so as provide an illustration of inside of the sphere 5a.

In another embodiment the light integrating sphere 5a comprises a sealing ring 53; in that embodiment the rotary table 150 is rotated about the rotary axis 154 to move the nest 151 on which light emitting device 91 have been loaded, so that the nest 151 abuts the sealing ring 53. the is rotated about the rotary axis 154 to move the nest 151 on which light emitting device 91 have been loaded, so that the nest 151 abuts the sealing ring 53. When the nest 151 abuts the sealing ring 53 the light emitting devices 91 will be in the test position. In a further variation of this embodiment the rotary table 150 is rotated about the rotary axis 154 to move the nest 151 on which light emitting device 91 have been loaded, so that the nest 151 abuts portion of the integrating sphere 5a in which the inlet window 51 is defined. When the nest 151 has been so that the nest 151 abuts portion of the integrating sphere 5a in which the inlet window 51 is defined the light emitting devices 91 will be in the test position. In all embodiments when the nest 151 is aligned with the inlet window 51, or when the nest 151 abuts portion of the integrating sphere 5a in which the inlet window 51 is defined, the light emitting devices 91 will extend above an inner surface of the light integrating sphere 5a.

In another embodiment the integrating sphere 5a first rotates about the rotary axis 154 so that the nest 151 is directly aligned below the inlet window 51 of the light integrating sphere 5a; and then the rotary table 150 is then moved linearly (i.e. moved in a direction parallel to the rotary axis 154) to move the nest 151 towards the inlet window 51, until the nest 151 abuts the integrating sphere 5a; specifically rotary table 150 is then moved linearly (i.e. moved in a direction parallel to the rotary axis 154) to move the nest 151 towards the inlet window, until the nest 151 abuts sealing ring 53 of the integrating sphere 5a. In one embodiment when the nest 151 abuts the sealing ring 53 it will optically seal the inlet window 51. In a preferred embodiment the shape and dimensions of the flat surface 153 of the nest 151 match (or are slightly larger than) the shape and dimension of the inlet opening 51 so that the nest 1 can optically seal the inlet window 51 when it is moved to abut the integrating sphere.

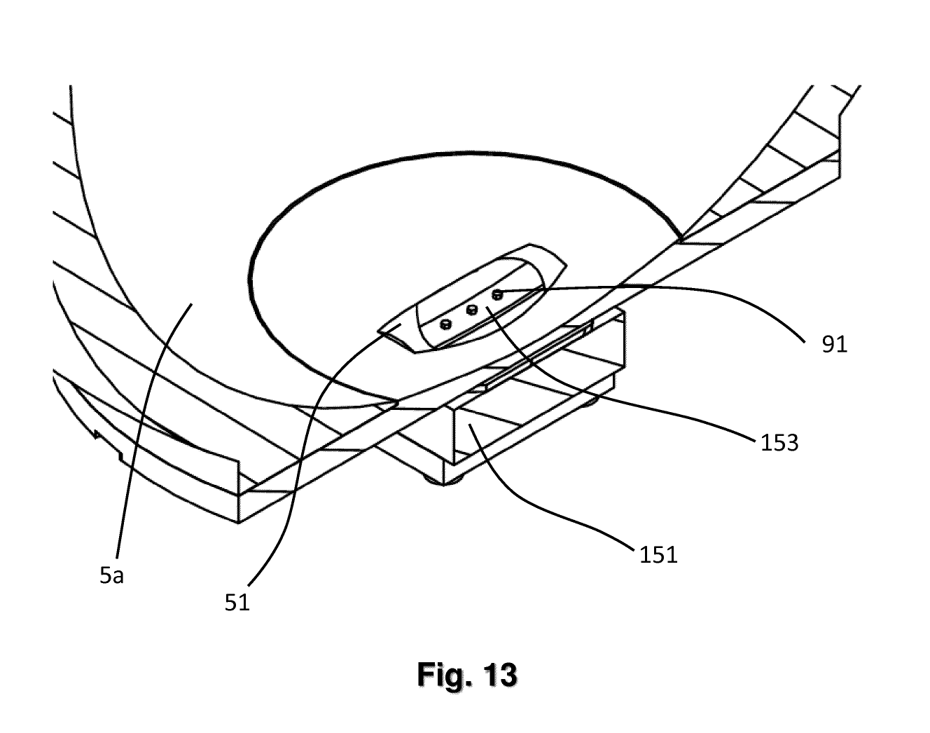

FIG. 13 provides a magnified view of the nest 151 on which light emitting devices 91 have been loaded, which is aligned with the inlet window 51 of the light integrating sphere 5a. The light emitting devices 91 extend above the inner surface 135 of the light integrating sphere 5a; and the intermediate electrical contact 160 provided in the nest 151 remain outside of the integrating sphere 5a. The inlet window 51 is shown to be rectangular shaped; the flat surface 153 of the nest 151 is also rectangular shaped and has a length and width dimensions which is larger than the respective length and width dimensions of the inlet window 51; this allows the nest 151 prevent at least some light (which has been emitted into the light integrating sphere 5a by the light emitting devices 91) from leaking out of light integrating sphere 5a. It is preferable that the dimensions and shape of the flat surface 153 are such that the full perimeter of the inlet window 51 can be fully contained within the perimeter of the flat surface 153 of the nest 151. It will be understood that it is not essential that the flat surface 153 have the same shape as the inlet window 53. In one embodiment the shape and dimension of the nest 151 will correspond to the shape and dimension of the inlet window 51 so that the nest 151 can optically seal the inlet window 51, however this is not essential.

Next electrical and optical testing of the light emitting devices 91 is then performed in the same manner as described above for the previous embodiment. The electrical signals which implement the electrical and/or optical testing are sent by the control and parameter measuring unit 3 to electrical contacts which are present at each of the designated areas 155 on the nest 151 where they are received by the electrical contacts of the light emitting devices 91.

The embodiments and aspects of the invention explained above are not determined to limit the scope of the invention, which is exclusively to be determined by the attached claims. Many modifications of the inventive concept are possible within the scope of the claims and, more specifically, arbitrary combinations of the several claim features are considered to be within the scope of the invention.

1. A method for testing electrical and optical parameters of a group of light-emitting devices, the method comprising the steps of,
bringing the group of devices to a test position wherein light emitted by the devices in the group can be received into an integrating sphere;
performing, electrical testing of the devices in the group in parallel, so that electrical parameters of each of the devices in the group can be determined;
performing, in a sequential device-by-device manner, optical testing of the devices in the group, so that optical parameters of each of the devices in the group can be determined.

2. A method according to claim 1 comprising the step of, bringing a plurality of groups of devices to a test position wherein light emitted by the devices in the plurality of groups can be received into an integrating sphere; and
for each group in the plurality of groups of devices, performing, electrical testing of the devices in the group in parallel, so that electrical parameters of each of the devices in the group can be determined, and performing, in a sequential device-by-device manner, optical testing of the devices in the group, so that optical parameters of each of the devices in the group can be determined, and
where the optical testing and/or electrical testing of the plurality of groups of devices is performed without moving the plurality of groups of devices from the initial test position to which the plurality of groups of devices were initially brought, so that the plurality of groups of devices are maintained in said test position as optical testing and electrical testing is performed on all devices in the plurality of groups of device.

3. A method according to claim 1 further comprising the steps of,
mechanically contacting a plurality of electrical contact pins with electrical contacts of all devices in the group, so that the plurality of electrical contact pins simultaneously mechanically contact electrical contacts of all devices in the group;
wherein each of the plurality of electrical contact pins can be used to supply electrical signals which implement said optical testing and/or can be used to supply electrical signals which implement said electrical testing.

4. A method according to claim 3, wherein the step of performing said electrical testing comprises, passing electrical signals which implement said electrical testing through each of the plurality of electrical contact pins simultaneously so that electrical testing of all the devices in the group is performed simultaneously.

5. A method according to claim 3, wherein the step of performing said optical testing comprises, passing electrical signals which implement said optical testing through each of the test contacts sequentially so that optical testing of all the devices in the group is performed in a sequential device-by-device manner.

6. A method according to claim 5, comprising the step of using a multiplexer to pass said electrical signals which implement said optical testing to each of the test contacts sequentially.

7. A method according to claim 1 wherein the step of performing electrical testing of the devices in the group in parallel is performed prior to the step of performing optical testing of the devices in the group in a sequential device-by-device manner.

8. A method according to claim 1, further comprising the step of,
determining, based on the optical testing, optical parameters of each of the devices in the group;
post-processing said optical parameters of each of the devices in the group, according to the position of the respective device relative to the center of the integrating sphere when the group is in said test position.

9. A method according to claim 1 comprising using a carrier to bring the group of devices to a test position,
wherein the carrier comprises a nest which comprises a flat surface on which a group of devices can be supported, and wherein the nest is configured such that no part of the nest extends above the plane of the surface, and
wherein each of the group of devices are supported on the flat surface so that each of the group of devices is above the nest.

10. A method according to claim 1 comprising using a carrier to bring the group of devices to a test position, wherein the carrier comprises a plunger head on which the group of devices can be supported, and wherein said step of bringing the group of devices to a test position comprises,
moving the carrier such that the plunger head, on which a tile containing the group of devices is supported, to a position below an inlet of a light integrating sphere,
moving the plunger head so that the tile is docked into a docking means which holds the tile in a position such that the group of devices are maintained in said test position.

11. A method according to claim 10 further comprising the steps of,
applying a vacuum to the tile to hold the tile on the plunger head as the carrier and plunger head are moved; and
removing the vacuum applied to the tile after the tile has been docked into the docking means.

12. A method according to claim 3 wherein the plurality of electrical contact pins are provided in a plunger head of a carrier, and wherein the step of mechanically contacting a plurality of electrical contact pins with electrical contacts of all devices in the group, so that the plurality of electrical contact pins simultaneously mechanically contact electrical contacts of all devices in the group, comprises,
applying a vacuum force to a tile on which the group of devices are supported, to suck the tile towards the plunger head and/or suck the plunger head towards the tray; and extending said plurality of electrical contact pins to mechanically contact the electrical contacts of all devices in the group.

13. An assembly suitable for performing the method according to claim 1, the assembly comprising,
a light integrating sphere;
a carrier for bringing the group of devices to a test position wherein light emitted by the devices in the group can be received into an integrating sphere;
a test control and parameter measuring unit for performing, electrical testing of the devices in the group in parallel, so that electrical parameters of each of the devices in the group can be determined, and for performing, in a sequential device-by-device manner, optical testing of the devices in the group, so that optical parameters of each of the devices in the group can be determined.

14. An assembly according to claim 13, further comprising, a plurality of electrical contact pins which can be selectively moved to mechanically contact the electrical contacts of all devices in the group, so that the electrical contact pins simultaneously mechanically contact respective electrical contacts of all devices in the group:
wherein each of the plurality of electrical contact pins can be used to supply electrical signals which implement said optical testing and/or can be used to supply electrical signals which implement said electrical testing; and
wherein the test control and parameter measuring unit is configured to initiate passing electrical signals which implement said optical testing through each of the electrical contact pins sequentially so that optical testing of all the devices in the group is performed in a sequential device-by-device manner, and wherein the test control and parameter measuring unit is configured to initiate passing electrical signals which implement said electrical testing comprises, through each of the plurality of electrical contact pins simultaneously so that electrical testing of all the devices in the group is performed simultaneously.

15. An assembly according to claim 13, wherein the assembly further comprises a means for maintaining the group of devices in said test position as the optical testing and electrical testing of the devices in the group is performed; and
wherein the test control and parameter measuring unit is configured to determine based on the optical testing, optical parameters of each of the devices in the group, and to post-process said optical parameters of each of the devices in the group, according to the position of the respective device relative to the center of the integrating sphere when the group is in said test position.
